(19) United States
(12) Patent Application Publication
(10) Pub. No.: US 2017/0020008 A1
(43) Pub. Date: Jan. 19, 2017

(54) Display System Having Borderless Design

(71) Applicant: AU OPTRONICS CORPORATION, Hsin-Chu (TW)

(72) Inventors: Chih-Hung Tsai, Hsin-Chu (TW); Hsueh-Hsing Lu, Hsin-Chu (TW); Chih-Pang Chang, Hsin-Chu (TW); Yu-Hsin Lin, Hsin-Chu (TW)

(21) Appl. No.: 15/208,904

(22) Filed: Jul. 13, 2016

(30) Foreign Application Priority Data
Jul. 17, 2015 (TW) 104123330

(51) Int. Cl. H05K 5/00

(52) U.S. Cl. CPC H05K 5/0021; H05K 5/0017

(57) ABSTRACT

A display system includes a first display panel, an extension display panel, and an optical covering layer. The first display panel has a first viewing area and a first peripheral strip adjacent to one side of the first viewing area. The extension display panel at least partially overlaps the image-displaying side of the first display panel and includes an extension viewing area. The extension viewing area at least partially overlaps the first peripheral strip within a projecting region of the first display panel and connects the first viewing area. The optical covering layer covers the image-displaying side of the first viewing area and the image-displaying side of the extension viewing area.

### BACKGROUND OF THE INVENTION

1. Field of the Invention

The present invention relates to a display system; particularly, the present invention relates to a display system combining multiple display panels.

2. Description of the Prior Art

With the development of the display technique, the quality of display devices is continuously improved. For a single display device, it is always one of important issues about how to increase the display area at a fixed size. The present display device utilizes narrow frame technique to decrease the peripheral area of the display device and increase the display area; however, the peripheral area is required to reserve some space for the gate driving circuit. Consequently, the peripheral area of the display device still has a certain width and the increase in display area is limited.

On the other hand, for a large-scale display scheme, when the manufacture process and cost are considered, the usual measure of forming a video wall is to combine different display devices to achieve a large-scale display. However, due to the reservation of space at the peripheral area of the display device mentioned above, when different display devices are combined, a visual effect having a plurality of dark lines at positions corresponding to peripheral areas of display devices is achieved since no picture is displayed on the peripheral areas. Therefore, the structure of the present display device needs to be improved.

### SUMMARY OF THE INVENTION

It is an object of the present invention to provide a display system which can increase the display area.

It is another object of the present invention to provide a display system which can decrease the influence of the border of the display panel on the display effect.

The display system includes a first display panel, an extension display panel, and an optical covering layer. The first display panel has a first viewing area and a first peripheral strip adjacent to one side of the first viewing area. The extension display panel at least partially overlaps an image-displaying side of the first display panel and includes an extension viewing area. The extension viewing area at least partially overlaps the first peripheral strip within a projecting region of the first display panel and connects the first viewing area. The optical covering layer covers the image-displaying side of the first viewing area and an image-displaying side of the extension viewing area. The range of display area can be expanded to the edge of the first display panel to achieve borderless effect by overlapping the first display panel and the extension display panel.

### BRIEF DESCRIPTION OF THE DRAWINGS

FIG. 1 is a perspective view of an embodiment of a display system of the present invention;

FIG. 2A and FIG. 2B are cross-sectional views of an embodiment of the display system of the present invention;

FIG. 3A and FIG. 3B are schematic views of a first image before/after connecting an extension image;

FIG. 4 and FIG. 5 are cross-sectional views of different embodiments of the display system of the present invention;

FIG. 6A is a perspective view of an embodiment of the display system of the present invention;

FIG. 6B is a schematic view of the first image of FIG. 6A after connecting the extension image;

FIG. 7 is a perspective view of another embodiment of the display system of the present invention;

FIG. 8 is a cross-sectional view of an embodiment of the display system of the present invention, and

FIG. 9A and FIG. 9B are schematic views of the first image before/after connecting a second image and the extension image.

### DETAILED DESCRIPTION OF THE PREFERRED EMBODIMENT

The present invention provides a display system having a continuous displaying image. The display system utilizes a first display panel and an extension display panel overlapping with each other to connect viewing areas of different display panels for achieving a continuous display image effect. Besides, viewing areas of different display panels have a common optical covering layer to integrate the manufacturing process after the display panels overlap with each other and together form a whole structure. The first display panel of the display system of the present invention can be a liquid crystal display panel, an electro-phoretic display panel, or an organic light-emitting diode (OLED) display panel; the extension display panel is preferably a flexible display panel.

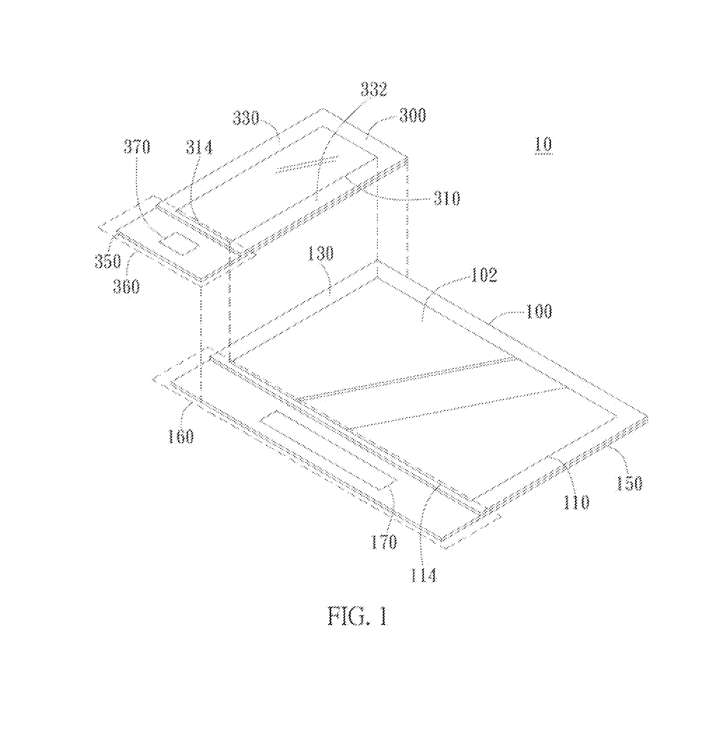

FIG. 1 is a perspective view of an embodiment of a display system of the present invention. As shown in FIG. 1, a display system 10 includes a first display panel 100 and an extension display panel 300. The first display panel 100 has a first viewing area 110 located on a display surface 102 and a first peripheral strip 130 adjacent to one side of the first viewing area 110. Besides, the first display panel 100 has a first bottom strip 160 distributed along a direction perpendicular to the first peripheral strip 130. The first bottom strip 160 is adjacent to a bottom edge 114 of the first viewing area 110 and vertically connected to the first peripheral strip 130. A first driving circuit 170 is disposed on the first bottom strip 160 to transmit display data for the first viewing area 110.

The extension display panel 300 includes an extension viewing area 310 and a first extension peripheral strip 330. The first extension peripheral strip 330 is adjacent to one side of the extension viewing area 310 away from the first viewing area 110. Besides, the extension display panel 300 includes a transparent second extension peripheral strip 332 adjacent to one side of the extension viewing area 310 facing the first viewing area 110. In other words, the first extension peripheral strip 330 and the second extension peripheral strip 332 are located at two sides of the extension viewing area 310, respectively. The first extension peripheral strip 330 is disposed away from the first viewing area 110 farther than the second extension peripheral strip 332 is. That is, the second extension peripheral strip 332 is disposed closer to the first viewing area 110 than the first extension peripheral strip 330 is. Besides, the extension display panel 300 has an extension bottom strip 360 distributed along a direction perpendicular to the first extension peripheral strip 330. As shown in FIG. 1, the extension bottom strip 360 is parallel to the first bottom strip 160. The extension bottom strip 360 is adjacent to a bottom edge 314 of the extension viewing area 310 and vertically connected to the first extension peripheral strip 330. An extension driving circuit 370 is preferably disposed on the extension bottom strip 360 to transmit display data for the extension viewing area 310; however, the location of disposing the extension driving circuit 370 is not limited to the position mentioned above. The extension driving circuit 370 and the first driving circuit 170 can be connected to the same signal source or different signal sources to obtain display data. In a different embodiment, the extension driving circuit 370 can be connected to the first driving circuit 170 for obtaining display data via the first driving circuit 170.

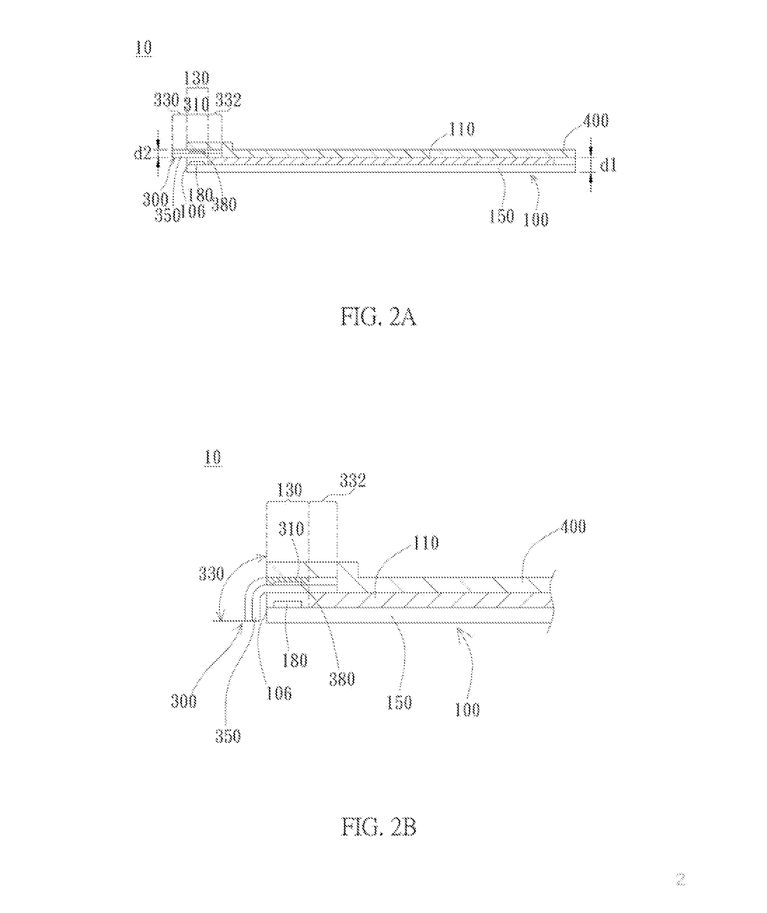

FIG. 2A and FIG. 2B are cross-sectional views of an embodiment of the display system 10 along the first bottom strip 160 of the present invention. As shown in FIG. 2A, the first display panel 100 has a first substrate 150, and the extension display panel 300 has an extension substrate 350 disposed on the first display panel 100. The extension display panel 300 has an extension gate driving circuit 380 preferably formed under the extension viewing area 310 to transmit driving signal for the extension viewing area 310; in addition, since the extension gate driving circuit 380 formed under the extension viewing area 310 rather that formed in the peripheral area around the viewing area, the width of the first extension peripheral strip 330 and the width of the second extension peripheral strip 332 can be reduced, but not limited to. A first gate driving circuit 180 is located under the extension display panel 300 and is formed in the first peripheral strip 130 of the first display panel 100 to transmit driving signal for the first viewing area 110.

As shown in FIG. 2A, the extension display panel 300 is stacked on the first display panel 100 and partially overlaps an image-displaying side of the first display panel 100. Specifically, the projection of the extension viewing area 310 on the first display panel 100 overlaps the first peripheral strip 130 and the projection of the extension viewing area 310 on the first display panel 100 connects the first viewing area 110. The first extension peripheral strip 330 protrudes over the first peripheral strip 130 and is located outside of the first display panel 100. The second extension peripheral strip 332 overlaps a portion of the first viewing area 110. In this way, the first bottom strip 160 can at least partially overlap the extension bottom strip 360 (referring to FIG. 1). The second extension peripheral strip 332 preferably covers a portion of the first viewing area 110. Because the second extension peripheral strip 332 is transparent or translucent, the image displayed on the first viewing area 110 can be seen via the second extension peripheral strip 332.

Besides, the display system 10 includes an optical covering layer 400. The optical covering layer 400 can be, for example, a polarizer film or a protection layer. After the extension display panel 300 is stacked on the first display panel 100, the optical covering layer 400 covers the image-displaying side of the first viewing area 110 and the image-displaying side of the extension viewing area 310 to form an integral structure. In other words, the optical covering layer 400 is disposed on the first display panel 100 and the extension display panel 300, crossing the first viewing area 110, the first peripheral strip 130, the second extension peripheral strip 332, and the extension viewing area 310. By utilizing the optical covering layer 400, the manufacturing process after the display panels are stacked can be simplified, and the total thickness can be reduced.

In an embodiment, the thickness (d1) of the first display panel 100 is preferably larger than the thickness (d2) of the extension display panel 300, i.e. the extension display panel 300 with smaller thickness is adopted to overlap the first display panel 100. For example, the first display panel 100 and the extension panel 300 are panels of different display types to have different thicknesses. For example, the first display panel 100 is a liquid crystal display panel, and the extension display panel 300 is a self-luminous panel. By this design, the difference in height between the first display panel 100 and the extension display panel 300 can be reduced, facilitating the optical covering layer to maintain a smooth surface.

As shown in FIG. 2B, after the optical covering layer 400 is disposed, the first extension peripheral strip 330 of the extension display panel 300 is bent away from a plane where the extension viewing area 310 lies, toward a sidewall 106 of the first display panel 100. In this embodiment, the flexibility of the first substrate 150 is smaller than the flexibility of the extension substrate 350, i.e. the extension substrate 350 is more flexible for bending. By this design, the display range can be extended from the first viewing area 110 toward outside of the first display panel 100, covering the location of the first peripheral strip 130 to minimize the border effect or to achieve the borderless effect.

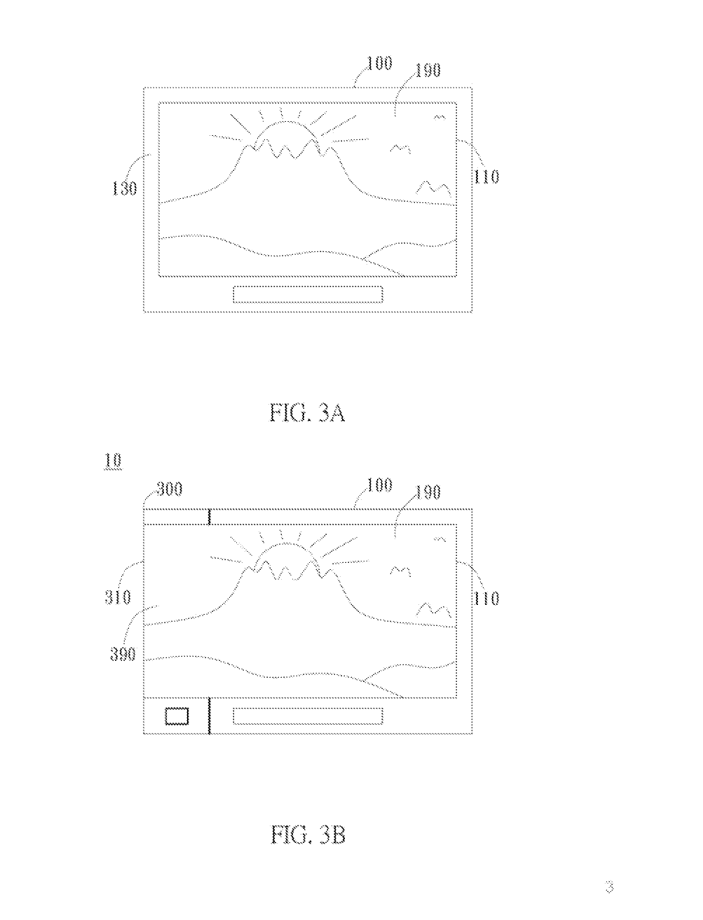

Please refer to schematic views of FIG. 3A and FIG. 3B, showing a first image 190 before/after connecting an extension image 390. As shown in FIG. 3A, the first viewing area 110 displays the first image 190. The first image 190 is surrounded by a certain width of peripheral space of the first display panel 100 so that the range of display area is smaller. When the extension display panel 300 is stacked on one side of the first display panel 100 where the first peripheral strip 130 locates, the first viewing area 110 and the extension viewing area 310 are connected. Besides, as mentioned above, the transparent second extension peripheral strip allows the display light from the first viewing area 110 to pass through the extension display panel 300. As such, the extension image 390 displayed on the extension viewing area 310 is combined with the first image 190 to achieve a continuous display image. As shown in FIG. 3B, the display system 10 can expand the original display range from the first peripheral strip 130 toward the edge of the first display panel 100 to minimize the border effect or to achieve the borderless effect.

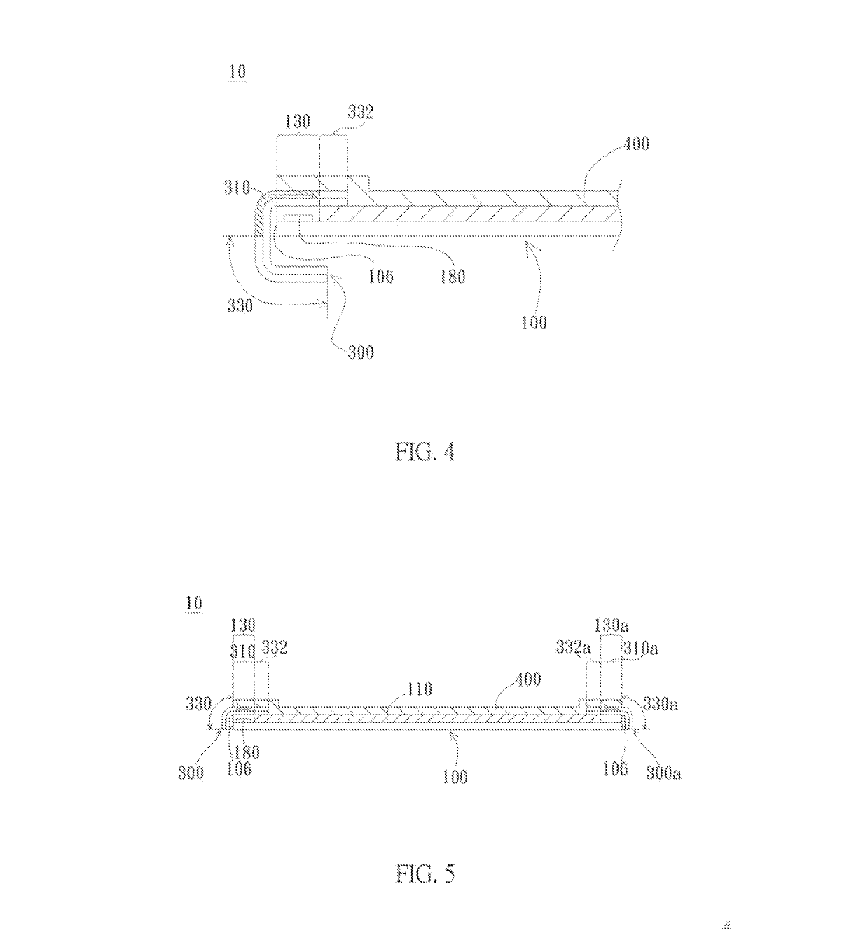

FIG. 4 and FIG. 5 are cross-sectional views of different embodiments of the display system of the present invention. As shown in FIG. 4, the extension display panel 300 can be designed with different sizes based on product requirements. For example, the extension display panel 300 illustrated in FIG. 4 has a longer size than the extension display panel 300 illustrated in FIG. 2A (i.e. the length from the first extension peripheral strip 330 to the second extension peripheral strip 332 is larger). For example, the length of the extension viewing area 310 and/or the length of the first extension peripheral strip 330 can be increased in this embodiment. In the display system 10 shown in FIG. 4, the projection of the extension viewing area 310 toward the first display panel 100 partially overlaps the first peripheral strip 130 and partially falls outside the first display panel 100, and the projection of the extension viewing area 310 on the first display panel 100 connects the first viewing area 110. In other words, the extension viewing area 310 partially protrudes beyond the first peripheral strip 130. The first extension peripheral strip 330 protrudes farther away from the first peripheral strip 130 and located outside of the first display panel 100. The first extension peripheral strip 330 and the portion of the extension viewing area 310 protruding outside the first peripheral strip 130 are together bent toward backside of the extension viewing area 310. By this design, the display system 10 not only can expand the display image from the image-displaying side of the first display panel 100 toward the first peripheral strip 130, but also further expand the display image to cover the sidewall 106 of the first display panel 100. As such, the display image has a display range including a horizontal plane (e.g. the plane where the first image 190 of FIG. 3B locates), a bending part (e.g. the curve portion of the extension viewing area 310 outside the first peripheral strip 130), and a vertical plane (e.g. the vertical portion of the extension viewing area 310 parallel to the sidewall 106 adjacent to the first peripheral strip 130) for providing a multi-viewing angle effect to users.

In another embodiment, as shown in FIG. 5, in addition to overlapping the extension display panel 300 onto the first peripheral strip 130, the display system 10 can stack another extension display panel 300a on the first display panel 100 to have an extension viewing area 310a overlap a peripheral strip 130a on the other side opposite to the first peripheral strip 130. The extension display panel 300a can adopt the same method mentioned above to overlap the extension viewing area 310a with the peripheral strip 130a to connect the first viewing area 100. A first extension peripheral strip 330a protrudes over the peripheral strip 130a and is located outside the first display panel 100. A second extension peripheral strip 332a overlaps the first viewing area 110. The optical covering layer 400 covers the image displaying sides of the first viewing area 110, the extension viewing area 310 and the extension viewing area 310a to form an integral structure. After the optical covering layer 400 is disposed, the extension display panel 300a can be bent backward. By this design, the display range can be extended from the first viewing area 110 toward two sides of the first display panel 100 to include the peripheral areas at two sides of the first viewing area 110 for minimizing the border effect or achieving the borderless effect.

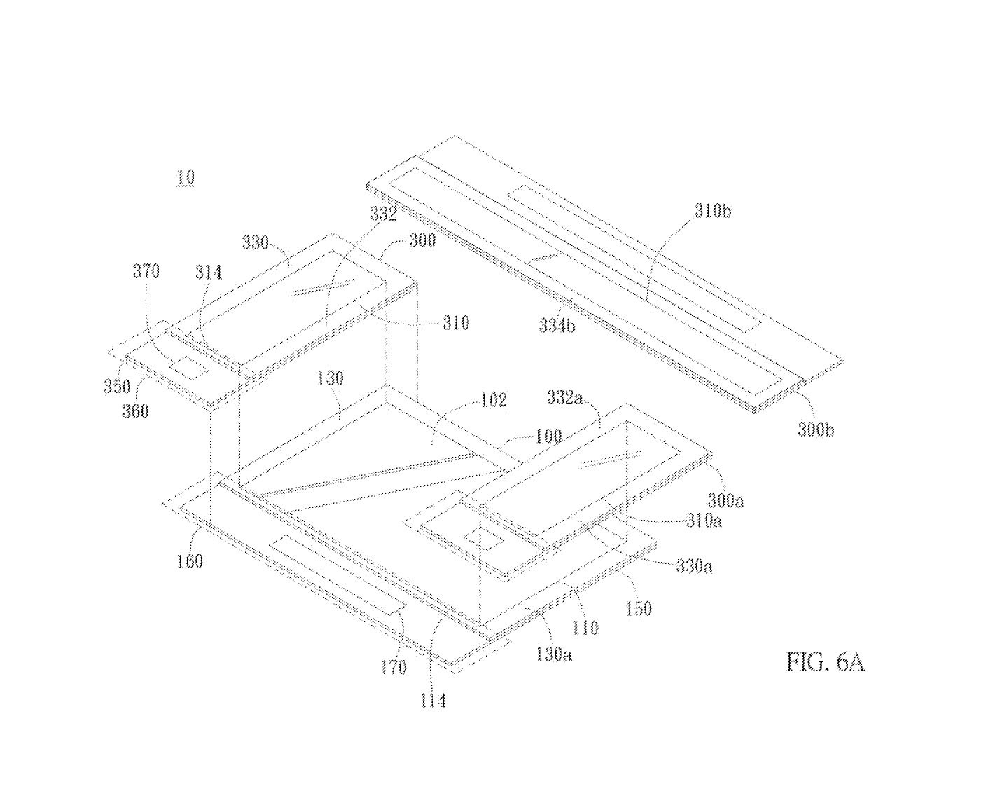

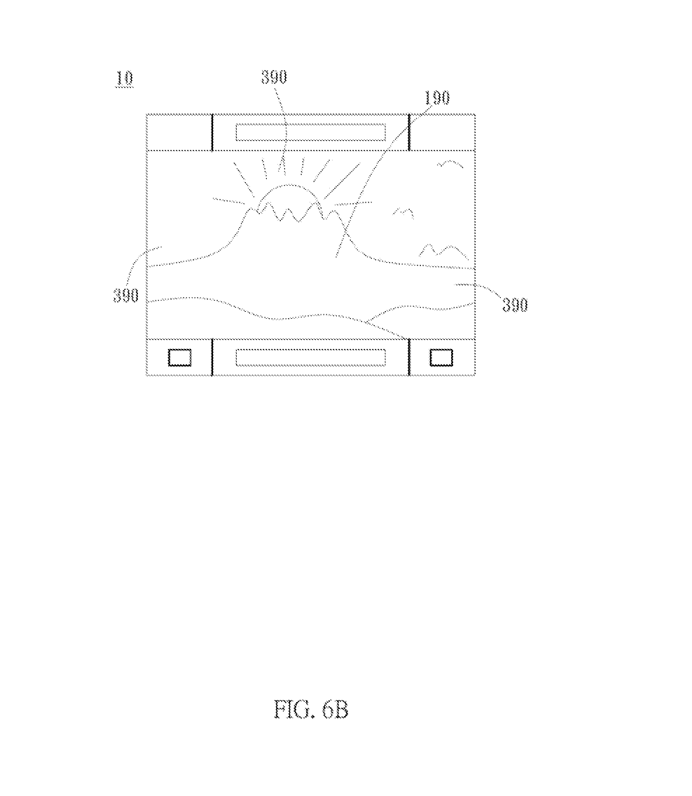

Another embodiment as shown in FIG. 6A, the display system 10 has a first display panel 100, two extension display panels (300, 300a) at two sides, and an additional extension display panel 300b distributed along a direction perpendicular to the first peripheral strip 130 and located at one side opposite to the first driving circuit 170. The extension display panel 300b includes a transparent third extension peripheral strip 334b adjacent to one side of the extension viewing area 310b facing the first viewing area 110 and one side of extension viewing areas (310, 310a). In this embodiment, the extension display panel 300 is stacked on and overlaps the first peripheral strip 130; the extension display panel 300a is stacked on and overlaps the peripheral strip 130a; the extension display panel 300b is stacked on and overlaps the extension display panels (300, 300a). The projection of the extension display panel 300b on the first display panel 100 at least partially overlaps the peripheral area perpendicular to the first peripheral strip 130. By this design, the projections of extension viewing areas (310, 310a) on the first display panel 100 connect the first viewing area 110, and the third extension peripheral strip 334b connects the first viewing area 110 and extension viewing areas (310, 310a) along the direction perpendicular to the first peripheral strip 130. Please refer to FIG. 6B. FIG. 6B is a schematic view of the first image of FIG. 6A after connecting the extension images. As shown in FIG. 6B, the display system 10 utilizes extension images 390 at three sides to connect the first image 190. As such, the original display range is expanded from the peripheral strips 130, 130a on two sides and the peripheral area opposite to the first driving circuit 170 to the corresponding edges of the first display panel 100 for minimizing the border effect or achieving the borderless effect.

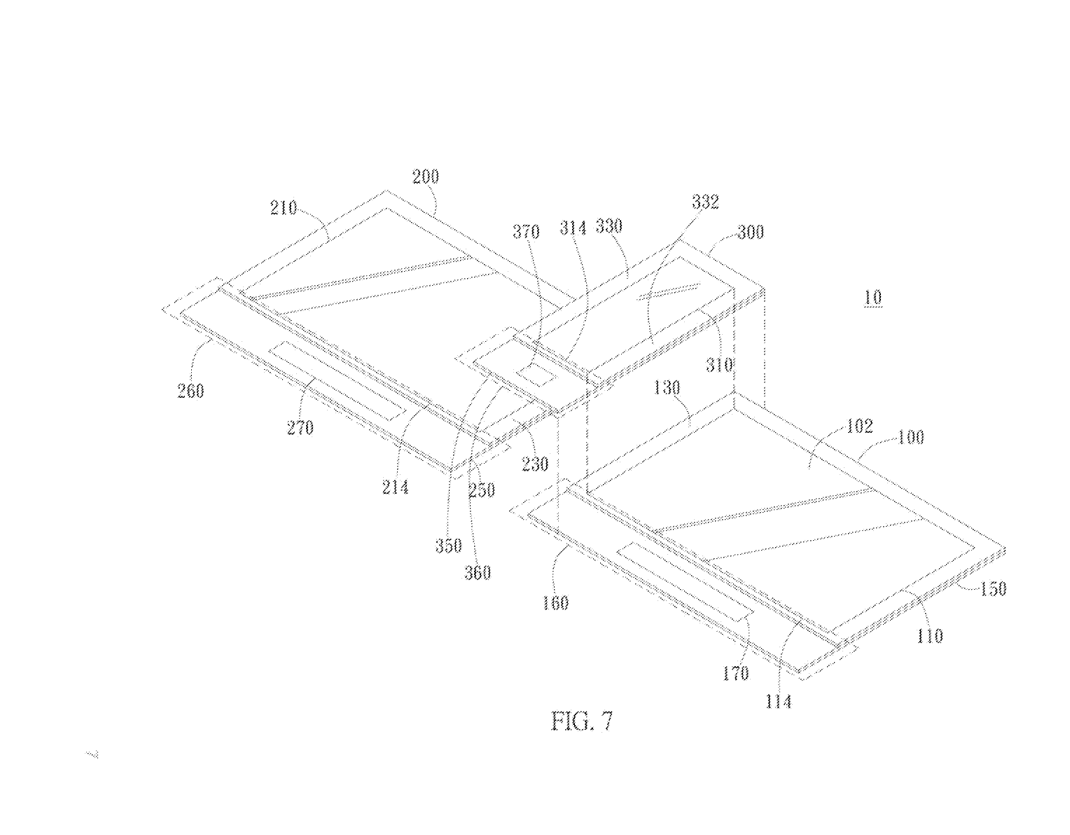

In addition to being utilized for a single display panel, the technique of the present invention can be also utilized for multiple display panels. Please refer to FIG. 7. FIG. 7 is a perspective view of another embodiment of the display system 10 of the present invention. As shown in FIG. 7, the display system 10 includes the first display panel 100, a second display panel 200, and the extension display panel 300. The second display panel 200 is located beside the first peripheral strip 130 and arranged abreast with the first display panel 100. The second display panel 200 has a second viewing area 210 and a second peripheral strip 230 adjacent to one side of the second viewing area 210 facing the first display panel 100. Besides, the second display panel 200 has a second bottom strip 260 distributed along a direction perpendicular to the second peripheral strip 230. The second bottom strip 260 is adjacent to a bottom edge 214 of the second viewing area 210 and vertically connected to the second peripheral strip 230. A second driving circuit 270 is disposed on the second bottom strip 260 to transmit display data for the second viewing area 210.

The extension display panel 300 includes the extension viewing area 310, the first extension peripheral strip 330, and the second extension peripheral strip 332. The first extension peripheral strip 330 is adjacent to one side of the extension viewing area 310 away from the first viewing area 110. The second extension peripheral strip 332 is adjacent to one side of the extension viewing area 310 facing the first viewing area 110. In other words, the first extension peripheral strip 330 is located near the second display panel 200; the second extension peripheral strip 332 is located near the first display panel 100. In addition, the extension display panel 300 has the extension bottom strip 360 distributed along the direction perpendicular to the first extension peripheral strip 330. As shown in FIG. 7, the extension bottom strip 360 is parallel to the first bottom strip 160. The extension bottom strip 360 is adjacent to the bottom edge 314 of the extension viewing area 310 and vertically connected to the first extension peripheral strip 330 and the second extension peripheral strip 332. The extension driving circuit 370 is preferably disposed on the extension bottom strip 360 to transmit display data for the extension viewing area 310; however, the location of disposing the extension driving circuit 370 is not limited to the position mentioned above. The extension driving circuit 370 and the first driving circuit 170 can be connected to the same signal source or different signal sources to obtain display data. In a different embodiment, the extension driving circuit 370 can be connected to the first driving circuit 170 for obtaining display data via the first driving circuit 170.

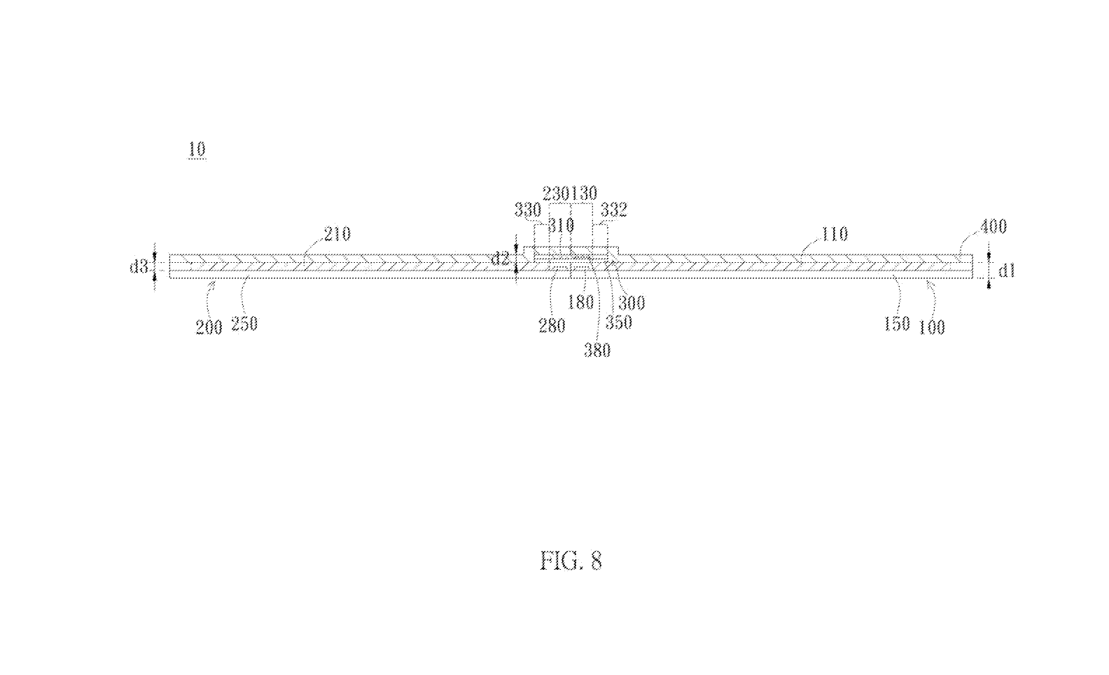

FIG. 8 is a cross-sectional view of an embodiment of the display system 10 of the present invention. As shown in FIG. 8, the first display panel 100 has the first substrate 150, the second display panel 200 has a second substrate 250, and the extension display panel 300 has the extension substrate 350 disposed on the first display panel 100 and the second display panel 200. The extension display panel 300 has the extension gate driving circuit 380 preferably disposed under the extension viewing area 310 to transmit driving signal for the extension viewing area 310; in addition, since the extension gate driving circuit 380 formed under the extension viewing area 310 rather that formed in the peripheral area around the viewing area, the width of the first extension peripheral strip 330 and the width of the second extension peripheral strip 332 can be reduced, but not limited to. The first display panel 100 has the first gate driving circuit 180 in the first peripheral strip 130, and the first gate driving circuit 180 is located under the extension display panel 300 to transmit driving signal for the first viewing area 110. Similarly, the second display panel 200 has a second gate driving circuit 280 in the second peripheral strip 230, and the second gate driving circuit 280 is located under the extension display panel 300 to transmit driving signal for the second viewing area 210.

As shown in FIG. 8, the extension display panel 300 at least partially overlaps the image-displaying side of the first display panel 100, and at least partially overlaps the image-displaying side of the second display panel 200. Specifically, the projection of the extension viewing area 310 on the first display panel 100 overlaps the first peripheral strip 130 and the extension viewing area 310 connects the first viewing area 110. The projection of the extension viewing area 310 on the second display panel 200 overlaps the second peripheral strip 230 and the extension viewing area 310 connects the second viewing area 210. The first extension peripheral strip 330 protrudes over the first peripheral strip 130 and located outside of the first display panel 100. Besides, the first extension peripheral strip 330 overlaps the second viewing area 210. On the other hand, the second extension peripheral strip 332 protrudes out of the second display panel 200 and overlaps the first viewing area 110. In this way, the first bottom strip 160 can at least partially overlap the extension bottom strip 360 (referring to FIG. 7). The second extension peripheral strip 332 preferably covers a portion of the first viewing area 110. Because the second extension peripheral strip 332 is transparent or translucent, the image displayed on the first viewing area 110 can still be seen via the second extension peripheral strip 332. Similarly, the first extension peripheral strip 330 preferably covers a portion of the second viewing area 210. Because the first extension peripheral strip 330 is transparent or translucent, the image displayed on the second viewing area 210 can still be seen via the first extension peripheral strip 330.

Besides, the display system 10 includes the optical covering layer 400. After the first peripheral strip 130 of the first display panel 100 is connected to the second peripheral strip 230 of the second display panel 200, the extension display panel 300 is stacked on the first display panel 100 and the second display panel 200. Then, the optical covering layer 400 covers the image-displaying sides of the first display panel 100, the second display panel 200, and the extension display panel 300 to form an integral structure. In other words, the optical covering layer 400 is disposed on the first display panel 100, the second display panel 200, and the extension display panel 300, crossing the first viewing area 110, the first peripheral strip 130, the extension display panel 300 (including the extension viewing area 310, the first extension peripheral strip 330, and the second extension peripheral strip 332), the second peripheral strip 230, and the second viewing area 210. By utilizing the optical covering layer 400, the manufacturing process after the display panels are assembled can be simplified, and the total thickness can be reduced.

As mentioned above, the thickness (d1) of the first display panel 100 is preferably larger than the thickness (d2) of the extension display panel 300. Besides, the thickness (d3) of the second display panel 200 is preferably larger than the thickness (d2) of the extension display panel 300. By this design, the difference in height between the first display panel 100 and the extension display panel 300, as well as the difference in height between the second display panel 200 and the extension display panel 300 can be reduced, facilitating the optical covering layer 400 to maintain a smooth surface.

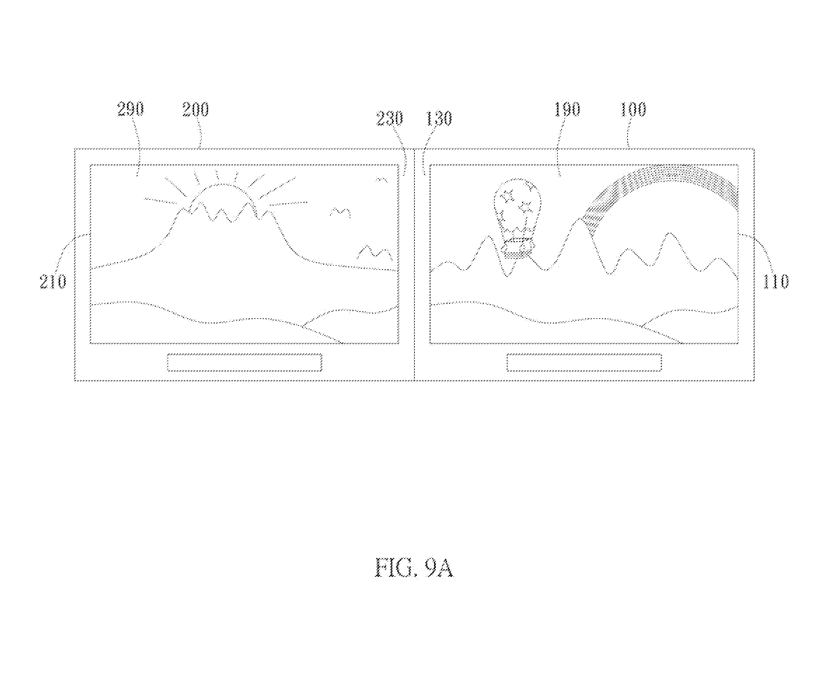

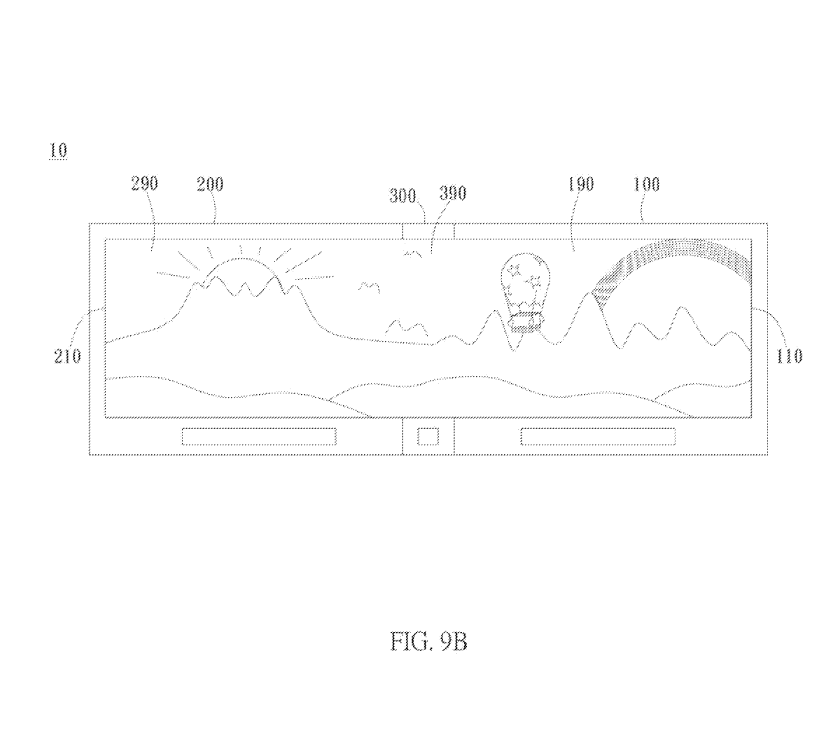

FIG. 9A and FIG. 9B are schematic views of the first image 190 before/after connecting a second image 290 and the extension image 390. As shown in FIG. 9A, the first viewing area 110 displays the first image 190, and the second viewing area 210 displays the second image 290. Since peripheral strips between the first display panel 100 and the second display panel 200 cannot display image, the first image 190 and the second image 290 look like two separate images. When the extension display panel 300 is stacked on the first display panel 100 where the first peripheral strip 130 locates and the second display panel 200 where the second peripheral strip 230 locates, the first viewing area 110, the extension viewing area 310, and the second viewing area 210 are continuously connected. The first image 190 and the second image 290 becomes a continuous image by connecting the extension image 390 generated from the extension viewing area 310. It is noted that the first extension peripheral strip 330 and the second extension peripheral strip 332 are translucent, so that the display light from the first viewing area 110 and the second viewing area 210 can pass through the extension display panel 300 to achieve a continuous image and eliminate the influence of the display panel border on the display effect. As shown in FIG. 9B, the display system 10 can expand the original display range toward the first peripheral strip 130 and the second peripheral strip 230 to form a continuous image.

To sum up, the display system of the present invention can utilize the extension display panel to increase the range of display area. When a single display panel is used, the extension display panel can shield the border of the display panel that does not display image and provide a continuous image, achieving the borderless effect. When multiple display panels are used, the extension display panel can cover the portions between display panels that does not display image. The extension display panel can provide the extension image, connecting separate images as an integral image and increasing the display range.

Although the preferred embodiments of the present invention have been described herein, the above description is merely illustrative. Further modification of the invention herein disclosed will occur to those skilled in the respective arts and all such modifications are deemed to be within the scope of the invention as defined by the appended claims.

What is claimed is:

1. A display system, comprising:
a first display panel having:
a first viewing area; and
a first peripheral strip adjacent to one side of the first viewing area;
an extension display panel being at least partially stacked on an image-displaying side of the first display panel, the extension display panel comprising an extension viewing area, a projection of the extension viewing area on the first display panel at least partially overlapping the first peripheral strip and the projection of the extension viewing area on the first display panel connecting the first viewing area; and
an optical covering layer covering the image-displaying side of the first viewing area and an image-displaying side of the extension viewing area.

2. The display system of claim 1, wherein the extension display panel comprises a first extension peripheral strip adjacent to one side of the extension viewing area away from the first viewing area, the first extension peripheral strip is bent away from a plane where the extension viewing area lies.

3. The display system of claim 2, wherein the extension display panel comprises a transparent second extension peripheral strip adjacent to one side of the extension viewing area facing the first viewing area, the second extension peripheral strip overlaps the first viewing area and is covered by the optical covering layer.

4. The display system of claim 2, wherein a thickness of the first display panel is larger than a thickness of the extension display panel.

5. The display system of claim 2, wherein the first display panel has a first substrate, the extension display panel has an extension substrate, and a flexibility of the first substrate is smaller than the flexibility of the extension substrate.

6. The display system of claim 1, further comprising a second display panel arranged abreast with the first display panel, the second display panel having:
a second viewing area; and
a second peripheral strip adjacent to one side of the second viewing area facing the first display panel;
wherein the extension display panel being at least partially stacked on an image-displaying side of the second display panel, a projection of the extension viewing area on the second display panel at least partially overlaps the second peripheral strip and the projection of the extension viewing area on the second display panel connecting the second viewing area; the optical covering layer covers the first display panel, the second display panel, and the extension display panel on image-displaying side.

7. The display system of claim 6, wherein the first peripheral strip is connected to the second peripheral strip.

8. The display system of claim 6, wherein the extension display panel comprises:
a transparent first extension peripheral strip adjacent to one side of the extension viewing area away from the first viewing area, the first extension peripheral strip overlapping the second viewing area; and
a transparent second extension peripheral strip adjacent to one side of the extension viewing area facing the first viewing area, the second extension peripheral strip overlapping the first viewing area;
wherein the first extension peripheral strip and the second extension peripheral strip are covered by the optical covering layer.

9. The display system of claim 6, wherein a thickness of the first display panel and a thickness of the second display panel are larger than a thickness of the extension display panel.

10. The display system of claim 1, wherein the first display panel has a first bottom strip adjacent to a bottom edge of the first viewing area and vertically connected to the first peripheral strip; the extension display panel has an extension bottom strip adjacent to a bottom edge of the extension viewing area and vertically connected to the first extension peripheral strip; a first driving circuit is disposed on the first bottom strip; an extension driving circuit is disposed on the extension bottom strip; the first bottom strip is parallel to and at least partially overlaps the extension bottom strip.

11. The display system of claim 1, wherein the first display panel and the extension display panel are panels of different display types.

12. The display system of claim 11, wherein the extension display panel is a self-luminous panel.

13. The display system of claim 1, wherein the extension display panel has an extension gate driving circuit formed under the extension viewing area.

14. The display system of claim 13, wherein a first gate driving circuit is located under the extension display panel in the first peripheral strip.

15. The display system of claim 1, wherein the first viewing area displays a first image; the extension viewing area displays an extension image; the extension image and the first image are continuous.
